(19) United States
(12) Patent Application Publication
(10) Pub. No.: US 2025/0135716 A1
(43) Pub. Date: May 1, 2025

(54) METHOD FOR PRODUCING A MAIN BODY OF AN OPTICAL ELEMENT FOR SEMICONDUCTOR LITHOGRAPHY, MAIN BODY, OPTICAL ELEMENT AND PROJECTION EXPOSURE APPARATUS

(71) Applicant: Carl Zeiss SMT GmbH, Oberkochen (DE)

(72) Inventors: Eduard SCHWEIGERT, Syrgenstein (DE); Heiko FELDMANN, Aalen (DE); Eric EVA, Aalen (DE); Johannes DITTRICH, Lorch (DE)

(21) Appl. No.: 19/008,824

(22) Filed: Jan. 3, 2025

Related U.S. Application Data
(63) Continuation of application No. PCT/EP2023/068297, filed on Jul. 4, 2023.

(30) Foreign Application Priority Data
Jul. 5, 2022 (DE) 10 2022 116 694.5
Jul. 5, 2022 (DE) 10 2022 116 695.3
Aug. 9, 2022 (DE) 10 2022 208 286.9

(51) Int. Cl. B29C 64/153; B33Y 10/00; B33Y 70/00; B33Y 80/00; G03F 7/00

(52) U.S. Cl. CPC B29C 64/153; B33Y 10/00; B33Y 70/00; B33Y 80/00; G03F 7/70316

(57) ABSTRACT

The disclosed techniques relate to a method for producing a base element of an optical element for semiconductor lithography, comprising the following steps: firstly, producing a material mixture comprising at least two material components; secondly, producing an intermediate element from the material mixture, wherein the material mixture comprises at least one first material component made of the material of the later base element, and wherein the material mixture comprises a second material component that functions to mechanically stabilise the intermediate element; thirdly, producing the base element from the intermediate element via temporary heating and at least partial removal of the second material component. The disclosed techniques also relate to an optical element produced using the method according to the disclosed techniques, a base element, an optical element, and a projection exposure system for semiconductor lithography provided with the optical element

### CROSS-REFERENCE TO RELATED APPLICATIONS

This is a Continuation of International Application PCT/EP2023/068297 which has an international filing date of Jul. 4, 2023, and the disclosure of which is incorporated in its entirety into the present Continuation by reference. This Continuation also claims foreign priority under 35 U.S.C. § 119(a)-(d) to and also incorporates by reference, in its entirety, German Patent Application DE 10 2022 116 694.5 filed on Jul. 5, 2022, German Patent Application DE 10 2022 116 695.3, filed Jul. 5, 2022, and German Patent Application DE 10 2022 208 286.9, filed Aug. 9,2022.

### FIELD

The techniques disclosed herein relate to a method for producing a main body for an optical element for a projection exposure apparatus for semiconductor lithography, and to an optical element produced by the method, to a main body and to a projection exposure apparatus.

### BACKGROUND

Projection exposure apparatuses for semiconductor lithography exhibit highly temperature-dependent behavior in terms of their imaging quality. Both elements that are not directly involved in the optical imaging, such as mounts and holders or housing parts, and optical elements themselves, such as lens elements or, in the case of EUV lithography, mirrors, change their extent, or surface shape, on being heated or cooled. These changes in extent and/or surface shape are directly reflected in the quality of the imaging of a lithography mask (for example, a phase mask, what is known as a reticle) on a semiconductor substrate (what is known as a wafer), that is performed by the system.

The heating of the individual components of the apparatus during operation is caused by the absorption of a portion of the radiation which is used to image the reticle on the wafer and is also referred to as used radiation. This radiation is generated by a light source, referred to below as used light source. In the case of EUV lithography, the used light source is a relatively complex plasma source, in which tin particles are laser-irradiated to generate a plasma which emits electromagnetic radiation in the desired short-wave frequency ranges.

Usually, projection exposure apparatuses are designed for a stationary state during operation, which is to say a state in which no significant changes in the temperature of apparatus components over time is to be expected. This temperature can be different for different optical elements, depending on the arrangement in the optical system. To minimize the above-described deformation and change over time of the optical elements, in particular of mirrors, a material with a low coefficient of thermal expansion is used for the main body, in particular of mirrors. For instance, it is possible, for example, by adding titanium oxide to set the coefficient of thermal expansion of a quartz glass in such a way that it is 0 for a certain temperature, what is known as the zero-crossing temperature. The coefficient of thermal expansion itself depends on the temperature and rises as the temperature rises, that is to say is negative at temperatures below the zero-crossing temperature and is positive at temperatures above the zero-crossing temperature.

The main bodies for the individual mirrors are set generally such that the zero-crossing temperature corresponds to the temperature which is constant during operation. Furthermore, attempts are made to make the gradient of the coefficient of thermal expansion as flat as possible, in order to keep the effect of deviations from the zero-crossing temperature on the surface shape of the mirrors as small as possible.

Furthermore, the power of the used light sources, which increases from one generation to the next, means it is necessary to control the temperature of at least individual mirrors by way of fluid channels provided in the main body. The prior art discloses methods for producing main bodies with integrated fluid channels, but they have the disadvantage that they are not suitable, or can be implemented only with great outlay, for materials with a predetermined zero-crossing temperature and a low gradient of the coefficient of thermal expansion.

### SUMMARY

An object of the techniques disclosed herein is to specify a method which eliminates the disadvantages known from the prior art. Another object of the disclosed techniques is to specify an improved optical element and an improved main body for semiconductor lithography and an improved projection exposure apparatus.

These objects may be achieved by the method and the devices having the features of the claims.

A method for producing a main body of an optical element for semiconductor lithography according to the disclosed techniques comprises the following steps:
firstly, producing a material mixture comprising at least two material components,
secondly, producing an intermediate body from the material mixture,
wherein the material mixture comprises at least one first material component made of the material of the later main body
and wherein the material mixture comprises a second material component which serves to mechanically stabilize the intermediate body,
thirdly, producing the main body from the intermediate body by temporarily heating and at least partially removing the second material component.

In one embodiment of the method, the at least one first material component may comprise a quartz glass powder, in particular a quartz glass powder doped with titanium oxide; the second material component may comprise at least one polymer. The first material component may also have multiple different titanium oxide concentrations each mixed with a second material component.

The titanium oxide brings about a reduction in the coefficient of thermal expansion of the first material and hence of the material mixture, which in the ideal case at the operating temperature of the optical element, i.e. the mean temperature established during operation, can be zero. The temperature at which the temperature-dependent coefficient of thermal expansion is zero is also referred to as zero-crossing temperature. To influence the zero-crossing temperature and the gradient of the coefficient of thermal expansion with a changing temperature, various measures can be employed. The level of the coefficient of thermal expansion largely depends on the proportion of titanium oxide in the predominantly silicon-oxide-comprising material as a percentage, with the coefficient of thermal expansion of the material mixture, i.e. of the main body, falling as the titanium oxide content rises, i.e. a curve of the coefficient of thermal expansion with respect to the temperature is shifted downward along the y axis. As a result, at the same time the zero-crossing temperature of the material mixture is shifted toward a higher temperature.

Subjecting the main body to heat treatment at a temperature between 900° C. and 1200° C. can, on the one hand, shift the curve of the coefficient of thermal expansion in the positive y direction, i.e. upward, as a result of which the zero-crossing temperature falls, and on the other hand, can advantageously reduce the gradient of the curve, with the result that around the zero-crossing temperature the change in the coefficient of thermal expansion in the event of temperature changes decreases.

In one embodiment of the disclosed techniques, the powder can be produced by grinding up a starting material with the predetermined physical properties of the main body or can be provided such that, after the production method according to the disclosed techniques, it corresponds to the predetermined physical properties of the main body.

Furthermore, a tool for grinding up the starting material may be made of the material of the first material component. This has the advantage that the first material component cannot be contaminated by wear of the tool owing to other substances which affect the physical properties of the main body.

As an alternative, the starting material can be pulverized contactlessly, for example by an ultrasound method.

In a further embodiment, the powder can be produced by a soot method.

Furthermore, a titanium oxide content in the ground-up or contactlessly produced powder, for a specimen of 1 g, deviates from a mean titanium oxide content of the main body by less than 5%, preferably less than 0.5%, particularly preferably less than 0.05%. This can be achieved, for example in comparison with conventional direct deposition or soot deposition, by a good mixing of the powder and/or by mixing different powder batches.

This has the advantage that, as a result, it is possible to set smaller fluctuations of the titanium oxide content over the later main body than would be possible with the existing production methods. This leads to an advantageously smaller fluctuation of the coefficient of thermal expansion over the main body.

The smaller the deviation, the lower the local inhomogeneities in the coefficient of thermal expansion, which depends, among other things, on the titanium oxide content. The coefficient of thermal expansion is also influenced by a heat treatment method implemented during or after the temporary heating of the main body and locally by a titanium oxide content that varies with the grain size and by the homogeneity of the grain sizes in the material mixture. To set the predetermined coefficient of thermal expansion, it is thus possible in a first step to set a low inhomogeneity of the titanium oxide content of the powder, and in a subsequent heat treatment method, to finally set the coefficient of thermal expansion.

In a further embodiment, the soot method can be carried out with an oxygen deficiency to improve the subsequent heat treatment process, as a result of which oxygen defects in the silicon oxide (Si₂O) created by the method form to an increasing degree. The hence increasingly arising silicon-silicon bonds (Si-Si) introduce an additional possible bonding angle, the effect of which is a better tension-relief option at high temperatures and thus a better heat treatability.

In particular, in the soot method at least one further substance can be added to modify the physical properties of the first material component, which enters into a covalent bond.

Suitable for this, in particular, is sodium (Na). As an alternative, to increase the heat treatability of the main body it is possible to perform doping with fluorine by treatment with a fluorine-containing gas or liquid.

In addition to the chemical composition, it is possible to set the grain size of the powder, which can, in particular, range from 100 nm to 500 μm. The variation in the grain size can be defined in, for example, that 90% of the grains are at least half the mean value and at most twice the mean value of the predetermined range.

Furthermore, the powder can be dried to reduce the OH content to an OH content of less than 100 ppm, preferably less than 30 ppm and particularly preferably less than 10 ppm.

A low OH content minimizes the risk of coefficients of thermal expansion that are established locally differently within the main body, this risk being brought about by the diffusion of OH during a subsequent sintering process. In this case, the heat treatability is impaired, as a result of which, as explained above, the curve of the coefficient of thermal expansion can also be raised less readily.

In this case, the deviation in the level of the coefficient of thermal expansion, or the position of the curve of the coefficient of thermal expansion with respect to the temperature, can be compensated beforehand by reducing the titanium oxide content by 0.1% to 0.5%.

This method has the advantage that the zero-crossing temperature can be very readily predicted via the titanium oxide content, and therefore, time-consuming heat treatment methods for setting can be at least minimized.

As an alternative, the powder can be moistened to increase the OH content to an OH content, based on the weight, of 700-1200 ppm. This makes it possible, in turn, to further improve the heat treatability of the main body created by the above-described production method.

In the selection of the OH content of the powder, therefore, it holds true for the first material component that an optimum has to be found between setting the gradient of the coefficient of thermal expansion via the temperature and setting the zero-crossing temperature, which is to say the absolute coefficient of thermal expansion, during the heat treatment and setting the homogeneity of the coefficient of thermal expansion in the main body.

A heat treatment required to set the coefficient of thermal expansion, its gradient and the zero-crossing temperature can be carried out after or during the temporary heating of the intermediate body in the third method step for producing the main body.

In particular, during the heat treatment, work can be performed with cooling rates of 0.2 K/h to 20 K/h.

The coefficient of thermal expansion of the material of the main body is set by the production method according to the disclosed techniques such that every mirror has a coefficient of thermal expansion of zero at the predetermined temperature, what is known as the zero-crossing temperature. Furthermore, the gradient of the coefficient of thermal expansion with respect to the temperature is made as flat as possible. To influence the zero-crossing temperature and the gradient of the coefficient of thermal expansion, measures in addition to those already explained can be employed.

In the case of a powder produced with oxygen defects, it is possible to sinter the main body in oxygen gas, the oxygen having the result that the oxygen defects convert to normal matrix bonds in (Si-O-Si). Since this happens at the sintering temperature, the matrix is fluid to a limited extent, on account of which a conversion takes place preferably at locations of increased local deformation, and this induces an advantageous relief of tension in the main body.

Furthermore, during the temporary heating operation, a static pressure can be exerted on the intermediate body. During what is referred to as sintering, an intermediate body, which was preformed beforehand by pressure or by the above-described method, made of powder is heated to a temperature close to the melting temperature of the material. Dring such sintering, bonds between the individual grains of the powder are formed through fusing, resulting in an at least virtually pore-free body.

In the case of a further method which works with a static pressure, what is known as bot isostatic pressing, a powder or solid, or else an already preformed intermediate body, is bonded to obtain a pore-free main body under the combination of a static pressure, such as in a pressure vessel, and simultaneous heating. In order that the static pressure acts on the powder or the later main body only from the outside, in the case of a powder it can be poured into a deformable gas-tight vessel. If an intermediate body is already present, it can be placed directly into the pressure vessel, the intermediate body needing to have a gas-tight outer layer. It is also possible to close residual bubbles in a body which has been completely sintered per se.

Furthermore, at least one functional surface, such as an optical effective surface of an optical element, made of the cured material mixture of the main body can be reworked by an abrasive method. The intermediate body can be produced at least partially by a 3D printing method.

In particular, the titanium oxide concentration can vary over the volume of the intermediate body part produced by a 3D printing method. The variation in the titanium oxide concentration can be set by the use of material mixtures with different titanium oxide concentrations. Depending on the method, it is thereby possible to set the titanium oxide concentrations of the material mixture per layer, within a layer or, like in the case of the polyjet method explained in more detail below, for each deposition of a further material mixture, for example in droplet form. The material mixtures are alternated or continuously mixed per layer or per partial deposition within a layer, which makes it possible to set a predetermined titanium oxide concentration.

Furthermore, the intermediate body can be produced using a mold, in particular printed into a mold by a 3D printing method. The mold can already contain the approximated surface shape of an optical effective surface of the optical element to be obtained. In this case, during the sintering, a gas-impermeable layer, which is advantageous for a later method step, for example hot isostatic pressing, can form in the material of the main body at the interface with the mold.

A main body of an optical element according to the disclosed techniques, for example a multi-layer mirror, can be produced, in particular, by one of the above-described embodiments of the method.

The main body can be distinguished in that the OH content of the material of the main body, based on the weight, is less than 100 ppm, preferably less than 30 ppm and particularly preferably less than 10 ppm. As a consequence of the method, this results in a gradient of the coefficient of thermal expansion of the material of the main body in a range of 1.5 ppb/K² and 2.3 ppb/K² at 20° C.

Furthermore, the titanium oxide content of the material of the main body can be at least 5%-15%, in particular 6.7%-8.5%, based on the weight. As mentioned above, it is possible, particularly in the case of a dry powder mixture, to set the zero-crossing temperature by reducing the titanium oxide content.

In a further embodiment, the main body may be built up layer by layer and the geometry at least of the outer layers can be adapted at least in certain regions to the geometry of the surface of the main body.

In the case of a projection exposure apparatus for semiconductor lithography which comprises an optical element according to the disclosed techniques, the main body of the optical element may be built up layer by layer. There may be inhomogeneities of material properties, such as the coefficient of thermal expansion, within the main body. The inhomogeneities can be brought about by the distribution of material components in the material mixture and/or by the production method. If the inhomogeneities, in a plane parallel to the optical effective surface, have a preferential direction, such as effects brought about by a 3D printing method, it is advantageous if the optical element is arranged in the projection exposure apparatus in such a way that the direction of the greatest inhomogeneities runs substantially perpendicularly in relation to a scanning direction of the projection exposure apparatus. This has the advantage that the imaging aberrations caused by the inhomogeneities can advantageously be averaged out, at least partially, during the scanning operation.

The method according to the disclosed techniques enables the straightforward production of complex geometries combined with setting of the coefficient of thermal expansion and the zero-crossing temperature, there being various parameters that partially have an opposite effect. The above-described combination possibilities and ranges are not exhaustive.

A further method for producing a main body for an optical element by an additive method according to the disclosed techniques comprises the following method steps:
providing a first material mixture, comprising a first carrier material and a first structural material,
providing a second material mixture, comprising a second carrier material and a second structural material,
the carrier materials comprising at least one monomer and/or at least one oligomer and the structural materials differing in terms of their composition,
forming an intermediate body by merging the material mixtures and polymerizing the carrier materials,
finishing at least one part of the main body by heating the intermediate body to thermally bond the structural materials and to remove the carrier materials.

In this context, a carrier material is to be understood as being a material which serves to temporary take up the structural material and provide a first mechanically stable structure for further processing. By contrast, the structural material is the material that, after the main body is finished, remains in it or forms it. The aforementioned first mechanically stable structure is obtained by polymerization of the monomers and/or oligomers of the carrier material. Since the intermediate body is produced by merging the material mixtures, it is possible to have the effect that, in certain regions, specific desired properties of the intermediate body and hence of the later main body can be obtained. The heating of the intermediate body to obtain the main body does not absolutely have to take place in a single step. It is by all means possible to firstly heat the intermediate body to such an extent that the polymers formed are removed by combustion and, in the same step, to provide a first bond, still only in parts, between the individual particles of the structural material.

A solid main body can then be produced in a subsequent sintering step. It is self-evident that, to produce a later optical element, the main body obtained in this way can also be provided with further sub-bodies which were produced by a different method than the method described, in particular, a conventional method.

The formation of an intermediate body can be performed using a polyjet printing method.

The polyjet method makes it possible to mix the material mixtures with one another at any location of the structure of the intermediate body in any desired settable ratio. The method is similar to the method used in the case of an inkjet printer, wherein setting the mixing ratios of the usually three primary colors (red, yellow, blue) and black makes it possible to print all colors. In the case of said method, a liquid carrier material containing slurried particles in the form of small droplets is applied and immediately cured after the application via ultraviolet irradiation. Furthermore, the use of the polymerization of the carrier material also makes it possible to easily produce a complex intermediate structure.

To obtain a main body for an optical element, it is advantageous if at least one of the structural materials contains a glass powder. The glass powder may contain, for example, quartz glass, and in particular, the glasses known under the trade names ULE or Zerodur.

Furthermore, at least one of the structural materials may contain an additive.

For instance, it is possible for a first structural material to contain only one of said glasses in powder form, whereas the second structural material, in the extreme case, is formed exclusively by a suitable additive. It is also possible for the two structural materials to differ in terms of the type of the additives.

The structural materials can also differ in terms of the concentration of the additives.

The additives may comprise, in particular, the following substances or compounds: titanium, titanium oxide, lithium, aluminum, OH compounds.

These additives are suitable, in particular, for setting a zero-crossing temperature of the coefficient of thermal expansion of the material of the resulting main body. The effect of titanium is, for example, to make it possible to set the coefficient of thermal expansion such that it can be zero or virtually zero, at least for a predetermined temperature range. Other additives may, for example, protect the material against embrittlement by electromagnetic radiation.

This opens up the possibility of setting the substance distribution during the production of the intermediate body in such a way that the concentration of the additives over the main body corresponds to a temperature distribution, established during use of the optical element, in the main body.

In other words, the zero-crossing temperature can be adapted in certain regions in such a way that, for a temperature distribution in the main body to be expected during operation of the associated projection exposure apparatus, the respective zero-crossing temperature prevails as far as possible everywhere in the main body. This makes it possible to have the effect that, in the event of temperature changes around the zero-crossing temperature, over large parts of the volume of the main body only small changes in shape occur owing to the temperature changes. The optical effective surface can likewise be formed such that it corresponds to its intended surface area in the case of the same temperature distribution.

Aside from focusing on a typical temperature distribution for the setting of the coefficient of thermal expansion over the main body, this temperature distribution can also vary such that, for a number X of possible temperature distributions, a deviation of the optical effective surface from its intended surface area is minimized. In this case, the spatial distribution of the additives in the main body would not be optimized for a certain temperature distribution selectively, but rather a thermal expansion behavior of the main body which, although it is not perfect, can be tolerated across the mentioned temperature distributions would be ensured.

In an advantageous variant of the disclosed techniques, the concentration of the additives can decrease as the distance from a side of the main body that is intended for an optical surface increases.

The gradient of the concentration can be geared for example to the material-specific heat flux and hence reduce deformations irrespective of a specific temperature distribution.

Furthermore, the concentration of the additives can constantly decrease as the distance from a side of the main body that is intended for an optical surface to a cooled layer in the main body increases.

This is the case for example in the case of an additive comprising titanium when optical elements that comprise, at a certain distance from the optical effective surface, fluid lines for controlling the temperature of the main body have been cooled. The temperature control can be regulated, for example, in such a way that, irrespective of the heat absorbed by the optical effective surface, the temperature of the main body underneath, that is to say on the side of the fluid lines that faces away from the optical effective surface, can be kept constant. The coefficient of heat transfer for this region would then be constant, by contrast to the region between the optical effective surface and the fluid lines.

It is also advantageous if the concentration of the additives in a predetermined partial region in the main body is set such that the coefficient of thermal expansion in the partial region is higher than in the rest of the volume of the main body.

This is the case whenever the main-body lower region which is remote from the optical effective surface side is to be intentionally thermally deformed. This predetermined and regulated deformation pushes through the main body as far as the optical effective surface and, at the same time, a heating of the optical effective surface by absorption and electromagnetic radiation does not bring about any parasitic deformations on the optical effective surface.

The method according to the disclosed techniques can be used, in particular, to produce an optical element for a projection exposure apparatus for semiconductor lithography.

A main body for an optical element according to the disclosed techniques is produced at least partially by an additive method, the zero-crossing temperature of the coefficient of linear thermal expansion continuously changing at least in a partial region of the main body.

In other words, the change in the zero-crossing temperature is selected such that no jumps occur in said partial region of the main body. This has the effect that although the corresponding partial region of the main body can have locally different coefficients of thermal expansion, there are no sharp boundaries between regions with different coefficients of thermal expansion. The result of this in turn is that, in the event of temperature changes, although the main body reacts locally in different ways, stress peaks at boundaries between regions with different coefficients of thermal expansion do not occur.

In particular, the change in the zero-crossing temperature ranges from 20° Celsius to 65° Celsius at more than 1 K/mm.

In an advantageous embodiment of the disclosed techniques, the zero-crossing temperature, which varies at least partially over the main body, corresponds to a temperature distribution, established during use of the optical element, in the main body.

The described measure bas the effect that, if the mentioned temperature distribution is present, the main body everywhere has a temperature which is in the region of the zero-crossing temperature. This, as mentioned above, minimizes thermally induced length changes across the main body. The mentioned variation in the zero-crossing temperature across the material of the main body can be adapted, in particular, to previously already known intensity distributions of the electromagnetic irradiation of the optical element, which is to say as a result of already known settings. The corresponding adaptations can also be made in the regions of the main body that are adjacent to the optical effective surface.

The mentioned setting of the coefficient of thermal expansion can, however, not only be used to minimize thermally induced length changes in the material of the main body. It is also possible to selectively create regions in the main body in which the coefficient of thermal expansion is increased with respect to the surrounding area.

In this case, there is the possibility of using heating or cooling of the corresponding region to selectively cause deformations on the effective surface of the optical element.

A projection exposure apparatus for semiconductor lithography that comprises optical elements which, in terms of the main body used, are designed as described, is distinguished by increased robustness with respect to thermal effects.

A further main body for an optical element according to the disclosed techniques, which comprises at least one actuator and/or sensor, is distinguished in that at least one actuator component of the actuator and/or one sensor component of the sensor is integrated at least in an additively manufactured partial structure of the main body. This has the advantage that the actuator component and/or the sensor component can be arranged closer to an optical effective surface or other functional elements, such as fluid channels, of the main body. This can enable direct detection of a deformation of the optical effective surface, as a result of which the accuracy and, in the case of a thermal sensor, also the reaction time to a change in the temperature on the optical effective surface are advantageously improved.

In particular, the actuator component and/or the sensor component may be an electrically conductive element. The electrically conductive element may be in the form of, for example, a wire, in particular a heating wire, or comprise electrically conductive particles. The wire may be inserted at a predetermined location during, for example, the production of the main body by a 3D printing method during the printing operation. In the case of a 3D printing method explained below, the particles can be integrated directly in one of the material mixtures used for the printing and be printed at predetermined positions in the main body. In a further variant of the disclosed techniques, the actuator component and/or the sensor component may comprise electrically conductive component parts. Electrically conductive component parts are to be understood as being, in particular, platelets, short wire or conductor portions, which are integrated in the material of the main body without further contact-connection. They differ from the aforementioned particles essentially only in that they generally cannot be directly printed, because they have a considerably greater extent than the particles. Nevertheless, there is of course the possibility of integrating the component parts in the material of the main body between the deposition of two layers in an additive method. For this, it would be possible, for example, to briefly interrupt a 3D print, insert the corresponding component part and then continue the print.

If the components are used as actuators, it is possible to generate an electrical current in the electrically conductive elements, whereupon the elements heat up owing to their ohmic resistance. As a result, the material of the main body in the surrounding area of the conductive elements is also heated and thereupon deforms, in particular expands, such that a deformation is obtained at the desired location in the main body. It is possible, for example in the case of heating wires, to connect the heating wires directly galvanically to a voltage source, in order to generate the necessary current. In the case of the use of particles or component parts without galvanic contact-connection to a voltage source, there is the option of generating the necessary electrical current by induction. For this, it is also possible to integrate induction coils in the main body, which on application of an AC voltage generate an alternating magnetic field and in this way cause eddy currents in the particles or component parts.

In a further advantageous embodiment of the disclosed techniques, the actuator component and/or the sensor component comprises magnetizable elements. These magnetizable elements may have a similar form to the aforementioned particles or component parts; they can in particular also coincide with them, since magnetizability and electrical conductivity are not mutually exclusive. In the case of magnetizable elements, a desired deformation can be achieved by generating a magnetic field in the region of the magnetizable elements. This can be achieved, for example, in that a DC voltage is applied to induction coils in the vicinity of the magnetizable elements, with the result that a temporally stable magnetic field is formed in the region of the magnetizable elements, whereupon the elements experience a magnetic force and deformation of the surrounding material occurs. In this case, the induction coils are used, i.e. in the manner of electromagnets. There is thus in principle also the possibility of using the same arrangement of coils and electrically conductive/magnetizable elements to achieve, on the one hand, a deformation via thermal expansion but also, on the other hand, a deformation via magnetic force. For the case involving magnetizable and electrically conductive elements, during operation of the coils as induction coils it must be ensured that the frequency of the applied AC voltage is kept sufficiently removed from the mechanical eigenfrequencies of the main body to avoid undesired mechanical vibrations in the main body.

For the operation of the aforementioned elements as sensors, there are various possibilities. For instance, it is possible to utilize the temperature dependence of the ohmic resistance in the event of the use of heating wires to, at certain points in time, determine the current resistance of the heating wires and, from that, deduce the temperature in the surrounding area. It is in principle also possible to use the integrated particles or component parts as sensor components, since they also exhibit temperature-dependent behavior in particular of their electrical properties. For instance, the inductance of an induction coil arranged in the region of the particles or component parts depends to a certain degree on the permeability, which for its part is temperature dependent, of the adjacent particles or component parts and also of the surrounding material. A determination of the current inductance of the coils can hence be taken as a basis to draw conclusions about the temperature in the region of the coils or in the region of the particles or component parts.

Furthermore, the actuator component and/or the sensor component may be a thermally conductive or heat-generating element. It may be in the form of a heat pipe, thermocouple or else a copper wire. The thermally conductive elements may be connected to a heat source and/or heat sink and used as thermal actuators. It is likewise also possible to use the integrated thermally conductive elements merely as an extension of a temperature sensor.

A further method for producing a main body for an optical element by an additive method according to the disclosed techniques comprises the following method steps:
producing at least a partial body, in the form of a connection geometry, of a predetermined structure of the main body by a polyjet method, the material mixture used to produce the main body comprising a carrier material containing at least one monomer and/or oligomer and a structural material containing a glass powder,
heating the main body, that was polymerized in the preceding method step, to thermally bond the glass powder constituents and to combust the polymer,
sintering the main body.

The method makes it possible to produce virtually any desired geometries, and transitions between the layers produced when the structure is being printed are no longer detectable in the end product.

Furthermore, two different material mixtures can be used in the production of the main body. This makes it possible to adapt the properties in different regions of the main body to different requirements, such as low coefficient of thermal expansion, high elasticity or high stiffness.

In particular, it is possible to produce a partial structure, comprising actuator components and/or sensor components, of the main body and the main body from two different material mixtures. This makes it possible to produce, for example, the connection geometry, such as the above-described thermally conductive element, with its connecting elements via a first material mixture with high elasticity. The rest of the main body can be produced from a second material mixture with high stiffness.

In particular, the main body may comprise a second partial structure which can be produced by a conventional manufacturing method. The individual partial structures can be connected to one another in a form fit or integral bond to obtain the main body.

### BRIEF DESCRIPTION OF THE DRAWINGS

Exemplary embodiments and variants of the disclosed techniques are explained in more detail below in conjunction with the drawings. In the figures:

FIG. 1 schematically shows a meridional section through a projection exposure apparatus for EUV projection lithography,

FIG. 2 schematically shows a meridional section through a projection exposure apparatus for DUV projection lithography,

FIG. 3 shows a flow diagram relating to a production method according to the disclosed techniques,

FIG. 4 shows a main body according to the disclosed techniques,

FIG. 5 shows a 3D printing machine (polyjet) for application of the method according to the disclosed techniques,

FIG. 6 shows a schematic depiction of a detail of the main body to explain the method,

FIG. 7 shows a flow diagram relating to a further production method according to the disclosed techniques,

FIG. 8 shows a further embodiment of the disclosed techniques,

FIG. 9 shows a further embodiment of the disclosed techniques,

FIG. 10 shows a further embodiment of the disclosed techniques, and

FIG. 11 shows a flow diagram relating to an alternative production method according to the disclosed techniques.

### DETAILED DESCRIPTION

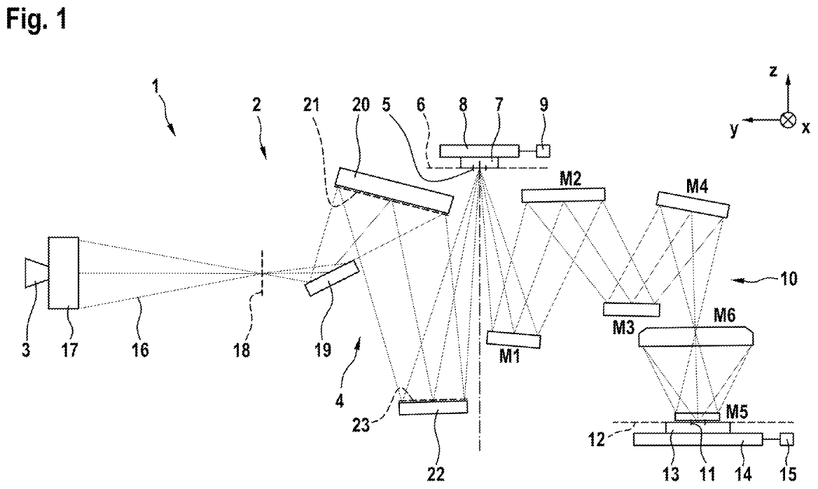

In the following text, the essential constituent parts of a microlithographic projection exposure apparatus 1 are described firstly with reference to FIG. 1 and by way of example. The description of the fundamental design of the projection exposure apparatus 1 and its constituent parts are not to be understood as limiting here.

One embodiment of an illumination system 2 of the projection exposure apparatus 1 has, in addition to a radiation source 3, an illumination optical unit 4 for illuminating an object field 5 in an object plane 6. In an alternative embodiment, the light source 3 may also be provided as a module separate from the rest of the illumination system. In this case, the illumination system does not comprise the light source 3.

A reticle 7 arranged in the object field 5 is illuminated. The reticle 7 is held by a reticle holder 8. The reticle holder 8 is displaceable by way of a reticle displacement drive 9, in particular in a scanning direction.

FIG. 1 depicts, for explanatory purposes, a Cartesian xyz coordinate system. The x direction runs perpendicularly into the plane of the drawing. The y direction runs horizontally and the z direction runs vertically. The scanning direction runs along the y direction in FIG. 1. The z direction runs perpendicularly in relation to the object plane 6.

The projection exposure apparatus 1 comprises a projection optical unit 10. The projection optical unit 10 serves for imaging the object field 5 into an image field 11 in an image plane 12. The image plane 12 extends parallel to the object plane 6. As an alternative, an angle that differs from 0° between the object plane 6 and the image plane 12 is also possible.

A structure on the reticle 7 is imaged on a light-sensitive layer of a wafer 13 arranged in the region of the image field 11 in the image plane 12. The wafer 13 is held by a wafer holder 14. The wafer holder 14 is displaceable by way of a wafer displacement drive 15, in particular along the y direction. The displacement on the one hand of the reticle 7 by way of the reticle displacement drive 9 and on the other hand of the wafer 13 by way of the wafer displacement drive 15 may take place in such a way as to be synchronized with one another.

The radiation source 3 is an EUV radiation source. The radiation source 3 emits in particular EUV radiation 16, which is also referred to below as used radiation, illumination radiation or illumination light. The used radiation has in particular a wavelength in the range between 5 nm and 30 nm. The radiation source 3 can be a plasma source, such as a laser-produced plasma (LPP) source or a gas discharge-produced plasma (GDPP) source. It may also be a synchrotron-based radiation source. The radiation source 3 can be a free electron laser (FEL).

The illumination radiation 16 emanating from the radiation source 3 is focused by a collector 17. The collector 17 can be a collector having one or more ellipsoidal and/or hyperboloid reflection surfaces. The illumination radiation 16 can be incident on the at least one reflection surface of the collector 17 with grazing incidence (GI), i.e. at angles of incidence of greater than 45° relative to the direction of the normal to the mirror surface, or with normal incidence (NI), i.e. at angles of incidence of less than 45°. The collector 17 can be structured and/or coated, firstly to optimize its reflectivity for the used radiation and secondly to suppress extraneous light.

Downstream of the collector 17, the illumination radiation 16 propagates through an intermediate focus in an intermediate focal plane 18. The intermediate focal plane 18 can constitute a separation between a radiation source module, comprising the radiation source 3 and the collector 17, and the illumination optical unit 4.

The illumination optical unit 4 comprises a deflection mirror 19 and, downstream thereof in the beam path, a first facet mirror 20. The deflection mirror 19 may be a plane deflection mirror or, alternatively, a mirror with a beam-influencing effect going beyond the pure deflection effect. As an alternative or in addition, the deflection mirror 19 may be in the form of a spectral filter that separates a used light wavelength of the illumination radiation 16 from extraneous light at a different wavelength. If the first facet mirror 20 is arranged in a plane of the illumination optical unit 4 that is optically conjugate to the object plane 6 as a field plane, it is also referred to as a field facet mirror. The first facet mirror 20 comprises a multiplicity of individual first facets 21, which are also referred to below as field facets. FIG. 1 depicts only some of these facets 21 by way of example.

The first facets 21 can be in the form of macroscopic facets, in particular in the form of rectangular facets or in the form of facets with an arcuate edge contour or an edge contour formed as partly circular. The first facets 21 may be in the form of plane facets or alternatively convexly or concavely curved facets.

As is known for example from DE 10 2008 009 600 A1, the first facets 21 themselves may each also be composed of a multiplicity of individual mirrors, in particular a multiplicity of micromirrors. The first facet mirror 20 can be in the form in particular of a microelectromechanical system (MEMS system). For details, reference is made to DE 10 2008 009 600 A1.

Between the collector 17 and the deflection mirror 19, the illumination radiation 16 travels horizontally, i.e. along the y direction.

In the beam path of the illumination optical unit 4, a second facet mirror 22 is disposed downstream of the first facet mirror 20. If the second facet mirror 22 is arranged in a pupil plane of the illumination optical unit 4, it is also referred to as a pupil facet mirror. The second facet mirror 22 may also be spaced apart from a pupil plane of the illumination optical unit 4. In this case, the combination of the first facet mirror 20 and the second facet mirror 22 is also referred to as a specular reflector. Specular reflectors are known from US 2006/0132747 A1, EP 1 614 008 B1, and U.S. Pat. No. 6,573,978.

The second facet mirror 22 comprises a plurality of second facets 23. In the case of a pupil facet mirror, the second facets 23 are also referred to as pupil facets.

The second facets 23 can likewise be macroscopic facets, which can, for example, have a round, rectangular or hexagonal boundary, or alternatively be facets composed of micromirrors. In this regard, reference is also made to DE 10 2008 009 600 A1.

The second facets 23 may have plane or alternatively convexly or concavely curved reflection surfaces.

The illumination optical unit 4 thus forms a double-faceted system. This basic principle is also referred to as a fly's eye integrator.

It can be advantageous to arrange the second facet mirror 22 not exactly in a plane that is optically conjugate to a pupil plane of the projection optical unit 10. In particular, the pupil facet mirror 22 can be arranged with a tilt relative to a pupil plane of the projection optical unit 10, as is described for example in DE 10 2017 220 586 A1.

The second facet mirror 22 is used to image the individual first facets 21 into the object field 5. The second facet mirror 22 is the last beam-shaping mirror or else actually the last mirror for the illumination radiation 16 in the beam path upstream of the object field 5.

In a further embodiment, which is not depicted, of the illumination optical unit 4, a transfer optical unit contributing in particular to the imaging of the first facets 21 into the object field 5 may be arranged in the beam path between the second facet mirror 22 and the object field 5. The transfer optical unit may have exactly one mirror or alternatively two or more mirrors, which are arranged one behind another in the beam path of the illumination optical unit 4. The transfer optical unit can in particular comprise one or two normal-incidence mirrors (NI mirrors) and/or one or two grazing-incidence mirrors (GI mirrors).

In the embodiment shown in FIG. 1, downstream of the collector 17 the illumination optical unit 4 has exactly three mirrors, specifically the deflection mirror 19, the field facet mirror 20 and the pupil facet mirror 22.

In a further embodiment of the illumination optical unit 4, the deflection mirror 19 can also be omitted, so that downstream of the collector 17 the illumination optical unit 4 can then have exactly two mirrors, specifically the first facet mirror 20 and the second facet mirror 22.

The imaging of the first facets 21 into the object plane 6 via the second facets 23, or using the second facets 23, and a transfer optical unit is generally only an approximate imaging.

The projection optical unit 10 comprises a plurality of mirrors Mi, which are consecutively numbered in accordance with their arrangement in the beam path of the projection exposure apparatus 1.

In the example depicted in FIG. 1, the projection optical unit 10 comprises six mirrors M1 to M6. Altematives with four, eight, ten, twelve or a different number of mirrors Mi are also possible. The penultimate mirror M5 and the last mirror M6 each have a passage opening for the illumination radiation 16. The projection optical unit 10 is a doubly obscured optical unit. The projection optical unit 10 has an image-side numerical aperture which is greater than 0.5 and can also be greater than 0.6 and can be for example 0.7 or 0.75.

Reflection surfaces of the mirrors Mi can be in the form of free-form surfaces without an axis of rotational symmetry. As an alternative, the reflection surfaces of the mirrors Mi may be in the form of aspherical surfaces with exactly one axis of rotational symmetry of the reflection surface shape. Just like the mirrors of the illumination optical unit 4, the mirrors Mi can have highly reflective coatings for the illumination radiation 16. These coatings may take the form of multilayer coatings, in particular with alternating layers of molybdenum and silicon.

The projection optical unit 10 has a large object-image offset in the y direction between a y coordinate of a center of the object field 5 and a y coordinate of the center of the image field 11. This object-image offset in the y direction can be of approximately the same magnitude as a z distance between the object plane 6 and the image plane 12.

The projection optical unit 10 can in particular have an anamorphic configuration. In particular, it has different imaging scales βx, βy in the x and y directions. The two imaging scales βx, βy of the projection optical unit 10 are preferably (βx, βy)=(+/−0.25, +/−0.125). A positive imaging scale β means imaging without an image inversion. A negative sign for the imaging scale β means imaging with an image inversion.

The projection optical unit 10 consequently leads to a reduction in size with a ratio of 4:1 in the x direction, i.e. in a direction perpendicular to the scanning direction.

The projection optical unit 10 leads to a reduction in size of 8:1 in the y direction, i.e. in the scanning direction.

Other imaging scales are likewise possible. Imaging scales with the same signs and the same absolute values in the x direction and y direction, for example with absolute values of 0.125 or 0.25, are also possible.

The number of intermediate image planes in the x direction and in the y direction in the beam path between the object field 5 and the image field 11 can be the same or can, depending on the embodiment of the projection optical unit 10, be different. Examples of projection optical units with different numbers of such intermediate images in the x and y directions are known from US 2018/0074303 A1.

A respective one of the pupil facets 23 is assigned to exactly one of the field facets 21, in each case to form an illumination channel for illuminating the object field 5. This may in particular result in illumination according to the Köhler principle. The far field is deconstructed into a multiplicity of object fields 5 via the field facets 21. The field facets 21 generate a plurality of images of the intermediate focus on the pupil facets 23 respectively assigned thereto.

The field facets 21 are each imaged by an assigned pupil facet 23 onto the reticle 7 in a manner overlaid on one another in order to illuminate the object field 5. The illumination of the object field 5 is in particular as homogeneous as possible. It preferably has a uniformity error of less than 2%, Field uniformity can be achieved by overlaying different illumination channels.

The illumination of the entrance pupil of the projection optical unit 10 can be geometrically defined by an arrangement of the pupil facets. The intensity distribution in the entrance pupil of the projection optical unit 10 can be set by selecting the illumination channels, in particular the subset of the pupil facets that guide light. This intensity distribution is also referred to as illumination setting.

A likewise preferred pupil uniformity in the region of portions of an illumination pupil of the illumination optical unit 4 that are illuminated in a defined way can be achieved by a redistribution of the illumination channels.

Further aspects and details of the illumination of the object field 5 and in particular of the entrance pupil of the projection optical unit 10 are described below.

The projection optical unit 10 may have in particular a homocentric entrance pupil. It may be accessible. It may also be inaccessible.

The entrance pupil of the projection optical unit 10 generally cannot be illuminated exactly via the pupil facet mirror 22. The aperture rays often do not intersect at a single point in the event of imaging by the projection optical unit 10 that telecentrically images the center of the pupil facet mirror 22 onto the wafer 13. However, it is possible to find an area in which the spacing of the aperture rays, which is determined in pairs, becomes minimal. This area represents the entrance pupil or an area conjugate thereto in real space. In particular, this area exhibits a finite curvature.

It may be the case that the projection optical unit 10 has different positions of the entrance pupil for the tangential beam path and for the sagittal beam path. In this case, an imaging element, in particular an optical component of the transfer optical unit, should be provided between the second facet mirror 22 and the reticle 7. Via this optical element, the different positions of the tangential entrance pupil and the sagittal entrance pupil may be taken into account.

In the arrangement depicted in FIG. 1 of the components of the illumination optical unit 4, the pupil facet mirror 22 is arranged in an area conjugate to the entrance pupil of the projection optical unit 10. The field facet mirror 20 is arranged with a tilt in relation to the object plane 6. The first facet mirror 20 is arranged with a tilt in relation to an arrangement plane defined by the deflection mirror 19.

The first facet mirror 20 is arranged with a tilt in relation to an arrangement plane defined by the second facet mirror 22.

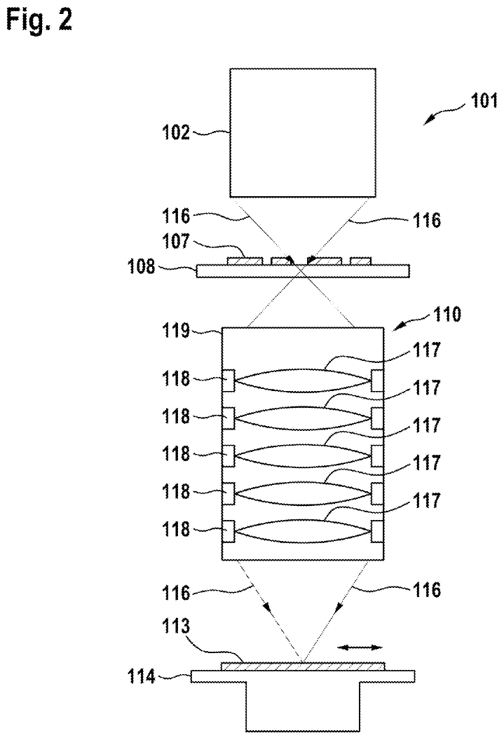

FIG. 2 schematically shows a meridional section through a further projection exposure apparatus 101 for DUV projection lithography, in which the disclosed techniques can likewise be used.

The design of the projection exposure apparatus 101 and the principle of the imaging are comparable with the design and procedure described in FIG. 1. Identical component parts are denoted by a reference sign increased by 100 with respect to FIG. 1, which is to say the reference signs in FIG. 2 start at 101.

By contrast to an EUV projection exposure apparatus 1 as described in FIG. 1, refractive, diffractive and/or reflective optical elements 117, such as lens elements, mirrors, prisms, terminating plates, and the like, can be used for imaging or for illumination in the DUV projection exposure apparatus 101 on account of the greater wavelength of the DUV radiation 116, employed as used light, in the range from 100 nm to 300 nm, in particular in the region of 193 nm. The projection exposure apparatus 101 in this case essentially comprises an illumination system 102, a reticle holder 108 for receiving and exactly positioning a reticle 107 which is provided with a structure and determines the later structures on a wafer 113, a wafer holder 114 for holding, moving, and exactly positioning this very wafer 113, and a projection lens 110, with multiple optical elements 117 held by way of mounts 118 in a lens housing 119 of the projection lens 110.

The illumination system 102 provides DUV radiation 116 required for the imaging of the reticle 107 on the wafer 113. A laser, a plasma source or the like can be used as the source of this radiation 116. The radiation 116 is shaped in the illumination system 102 by means of optical elements such that the DUV radiation 116 bas the desired properties in terms of diameter, polarization, shape of the wavefront and the like when it is incident on the reticle 107.

Apart from the additional use of refractive optical elements 117, such as lens elements, prisms, terminating plates, the setup of the downstream projection optical unit 101 with the lens housing 119 does not differ in principle from the setup described in FIG. 1 and is therefore not described in further detail.

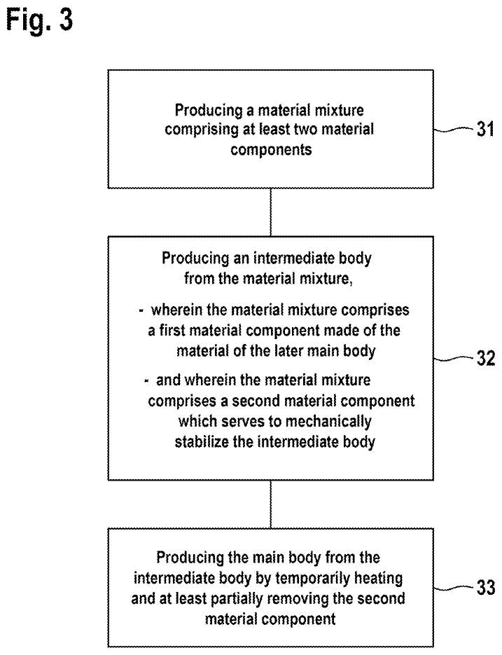

FIG. 3 shows a flow diagram of a possible production method for a main body of an optical element for semiconductor lithography, which can be used for example in one of the two apparatuses described in the preceding figures.

In a first method step 31, a material mixture comprising at least two material components is produced.

In a second method step 32, an intermediate body is produced from the material mixture, wherein the material mixture comprises at least a first material component made of the material of the later main body and wherein the material mixture comprises a second material component which serves to mechanically stabilize the intermediate body.

In a third method step 33, the main body is produced from the intermediate body by temporarily heating and at least partially removing the second material component.

The first material component, which comprises a quartz glass, in particular a quartz glass doped with titanium oxide, is fed to the material mixture as a powder. It is produced by grinding up a starting material such that the physical properties of the powder correspond to those of the later main body, or is provided such that, after the production method according to the disclosed techniques, the predetermined physical properties of the main body are obtained.

The tools used in the grinding-up of the starting material are advantageously produced from the same material as a material of the first material component, or produced from materials used in the first material component, which makes it possible to avoid contamination of the first material component owing to wear of the tool. Furthermore, a contactless method, such as an ultrasound method, can also be used to pulverize the starting material.

As an alternative, the first material component can be produced by what is known as a soot method, in which firstly sand is reduced with carbon and then the resulting silicon is converted to silicon tetrachloride with chlorine. Then, in a high-temperature pyrolysis, a homogeneous mixture of vaporous silicon tetrachloride, hydrogen, oxygen and an inert gas is combusted with a burner in a cooled combustion chamber. Initially formed in the flame are droplet-like silicon dioxide particles, which attach to one another in chains and through branching form three-dimensional secondary particles. These particles accumulate in turn to form tertiary particles, which precipitate as powder in the chamber.

The burner flame used in the soot method can be deliberately produced with an oxygen deficiency, as a result of which oxygen defects in the silicon oxide (Si₂O) created by the method form to an increasing degree. The hence increasingly arising silicon-silicon bonds (Si-Si) introduce an additional possible bonding angle, the effect of which is a better tension-relief option at high temperatures and thus a better heat treatability. This makes it easier to set the physical properties of the main body with respect to the coefficient of thermal expansion and the above-described zero-crossing temperature. The coefficient of thermal expansion of the material of the main body is set by the production method according to the disclosed techniques such that every mirror has a coefficient of thermal expansion of zero at the predetermined temperature, what is known as the zero-crossing temperature.

Furthermore, the gradient of the coefficient of thermal expansion with respect to the temperature is made as flat as possible. To influence the zero-crossing temperature and the gradient of the coefficient of thermal expansion, various measures can be employed.

The level of the coefficient of thermal expansion largely depends on the proportion of titanium oxide in the predominantly silicon-oxide-comprising material as a percentage, with the coefficient of thermal expansion of the material mixture, i.e. of the main body, falling as the titanium oxide content rises, i.e. a curve of the coefficient of thermal expansion with respect to the temperature is shifted in the negative y direction. As a result, at the same time the zero-crossing temperature of the material mixture is shifted toward a higher temperature. Subjecting the main body to heat treatment at a temperature between 900° C. and 1200° C., on the one hand, shifts the curve of the coefficient of thermal expansion in the positive y direction, i.e. upward, as a result of which the zero-crossing temperature falls, and on the other hand, advantageously reduces the gradient of the curve.

It is also possible for the main body to be sintered in oxygen gas, the oxygen having the result that the oxygen defects convert to normal matrix bonds in silicon oxide bonds (Si-O-Si). Since this happens at the sintering temperature, the matrix is fluid to a limited extent, as a result of which a conversion takes place preferably at locations of increased local deformation, and this induces a relief of tension in the main body.

In addition, it is possible already in the soot method to add metals which enter into a covalent bond. Suitable here in particular is sodium (Na). As an alternative, to increase the heat treatability of the main body it is possible to dope the powder with fluorine by treatment with a fluorine-containing gas or liquid.

As an alternative, the flame can also be operated with an oxygen excess, which results in the formation of peroxide centers, which is to say regions with a Si-O═O-Si bond. They may be reduced by sintering in a reducing atmosphere, such as a hydrogen atmosphere, which results in the formation of normal matrix bonds and water vapor, which can escape before the sintering is concluded, in particular when sintering is performed under reduced pressure or at least at a very low water vapor pressure. Besides the hydrogen atmosphere, it is alternatively also possible to perform sintering in a vacuum or in a carbon monoxide (CO) or ammonia (NH₃) atmosphere.

In particular, it is possible after the soot method, after which the powder has a OH content, based on the weight, of 150-300 ppm, to bring the powder to an OH content of 700-1200 ppm by moistening it, as a result of which, in turn, the heat treatability of the main body created by the above-described production method is improved.

As an alternative, the powder can also be dried to an OH content of less than 100 ppm, preferably less than 30 ppm and particularly preferably less than 10 ppm. A low OH content minimizes the risk of coefficients of thermal expansion that are established differently within the main body, this risk being brought about by the diffusion of OH during a subsequent sintering process. In this case, the heat treatability is impaired, as a result of which, as explained above, the curve of the coefficient of thermal expansion can also be raised less readily. The deviation of the magnitude of the coefficient of thermal expansion can be compensated beforehand by reducing the titanium oxide content by 0.1% to 0.5% in comparison with conventionally produced materials. This method has the advantage that the zero-crossing temperature can be very readily predicted via the titanium oxide content, and therefore, time-consuming heat treatment methods for setting the zero-crossing temperature can be at least minimized. In the selection of the OH content of the powder, therefore, it holds true for the first material component that an optimum has to be found between setting the gradient of the coefficient of thermal expansion via the temperature and setting the zero-crossing temperature, which is to say the absolute coefficient of thermal expansion, during the heat treatment and setting the homogeneity of the coefficient of thermal expansion in the main body.

In the exemplary embodiment described here, the intermediate body can be produced from the material mixture by what is known as a polyjet method, which is similar to an inkjet printing method. The intermediate body is built up layer by layer, the minimum resolution depending on the layer thickness created by the printer. The layer thickness is determined, on the one hand, by the grain size of the material components and, in the case of a polyjet method, by the metering of the liquid material mixture.

The titanium oxide concentration of the material mixture used can be reset with each deposition by using at least two printheads, which advantageously makes it possible to set the titanium oxide concentration selectively over the volume of the optical element. As a result, it is possible to set different zero-crossing temperatures, which can be deduced from the temperature distributions in the main body that arise during operation, in various regions of the main body.

In particular, by virtue of the virtually as-desired configuration of the body in the case of the polyjet method, the last layers of the intermediate body can be formed such that they are parallel to the later optical effective surface.

As an alternative, the intermediate body can also be created layer by layer by powder-bed laser sintering or a stereolithographic method, to cite only a few possibilities.

In the case of each of these methods and also in the case of further possible production methods, such as an injection molding method, a conventional molding method or an embossing method, use is made of a material mixture. The first material component, which later on forms the main body, is identical except for requirements specific to the respective method, such as the above-described moisture and/or titanium oxide concentration. The second material component, which decisively determines the physical properties, such as liquid or solid, and the melting temperature, which is important in the case of injection molding, of the material mixture that are necessary for the method, by contrast significantly differs.

As a further variation, a 3D print can also be implemented directly in a mold in the form of a shell. This makes it possible to predetermine for example the shape of that surface of the main body on which the optical effective surface is formed in the further course of the method. Printing into or onto a shell has the advantage that, during the sintering operation, a gas-tight layer necessary for a later hot isostatic pressing operation already forms at the interface with the shell.

If, in the case of a 3D printing method, the layers are also built up at the same time as the later optical effective surface, besides the vertical layering it is also possible to form a horizontal layering which is rastered within the vertical layers and is parallel to the mirror surface. As a result, inhomogeneities in the coefficient of thermal expansion are brought about both along the printing direction and perpendicularly thereto. The direction with the greatest inhomogeneities, which can be determined for example by measurements, is aligned perpendicularly in relation to the scanning direction, illustrated in FIG. 1 and FIG. 2, of the projection exposure apparatus, and therefore the effect on the imaging quality is determined by the scanning.

The intermediate body is sintered, and this results in the combustion of the second material component, which is in the form of a polymer in the described embodiment, and the bonding of the individual grains of the powder of the first material component to obtain the main body. The combustion of the second material component and the bonding of the grains of the powder to obtain the main body can alternatively also be carried out in two separate method steps. In a first step, the second material component is combusted (pyrolysis), the grains of the powder already bonding at certain points. In a second step, the main body is sintered, with a pore-free main body being produced from the already bonded grains. Furthermore, removal of a first proportion of the polymer, such as polyethylene glycol, from the intermediate body can also be realized by insertion into an aqueous liquid and removal of the other proportion, such as polyvinyl butyral, can be realized by subsequent combustion (pyrolysis). The two-stage method for the removal of the various materials of the second material component has the advantage that, after the polyethylene glycol has been released, an open-pore structure is produced, as a result of which the mass to be removed by pyrolysis is lower and can be removed from deeper layers, as a result of which in turn the wall thickness of the main body can advantageously be made larger.

A residual porosity present after the sintering operation can be closed by hot isostatic pressing (HIP), the surface of the main body needing to be gas-tightly closed for this. This can be brought about by exposing the surfaces to the flow of a hot gas, preferably comprising an inert gas.

As an alternative, the intermediate body can also be dipped into a suitable aqueous solution, which only penetrates to a depth of a few micrometers to 1 mm, and then dries or reacts, as a result of which a gas-tight surface layer which is stable at the temperature used during the hot isostatic pressing operation is formed. Instead of the solution, it is also possible to use a melt of a mixed glass, for example a sodium silicate glass, as a result of which it is also possible to form a gas-tight surface layer. It is also possible, after the combustion of the second material component by the above-described method, to apply a gas-tight surface layer to the intermediate body and do without sintering of the intermediate body. This has the advantage that the bonding of the powder of the first material component to obtain a pore-free glass body, owing to the higher pressure during the hot isostatic pressing operation, is achieved at lower temperatures. This advantageously minimizes the risk of displacement and/or deformation of fluid channels, which have been integrated in the intermediate body and in part can have inside diameters of a few um, owing to the pressure which also acts in the fluid channels when the powder is bonded.

The heat treatment for setting the gradient of the coefficient of heat transfer and the zero-crossing temperature, as explained above, can also be implemented by predetermined cooling rates, which may range from 0.2 K/h to 20 K/h, during the hot isostatic pressing operation. A further advantage of the hot isostatic pressing operation is that, the further removed the temperature used is from the melting temperature of the material of the main body, the more dimensionally stable the material is, as a result of which the geometry and the position of structures introduced in the main body, for example fluid channels, are retained.

The shrinkage, which occurs during the sintering and/or during the hot isostatic pressing owing to the bonding of the grains and the release of the second material component, ranges from 5% to 20%, in particular 5% to 10%. This shrinkage depends on the proportion of the first material component in the material mixture as a percentage. By way of tests in terms of the specific geometries of the main body, it is also possible to compensate for nonlinear shrinkage brought about on the basis of inhomogeneities in the material mixture or by the method.

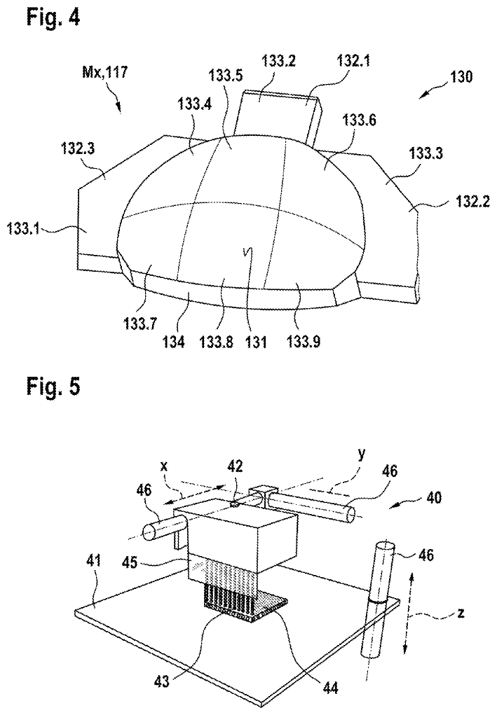

FIG. 4 shows an optical element according to the disclosed techniques which is in the form of a mirror Mx, 117 and has a main body 130, which has three connections 132.1, 132.2, 132.3 and an optical region 134, which comprises the optical effective surface 131. The main body 130 also comprises material zones 133.1-133.9 which were obtained at least partially in accordance with the production method described below. They differ in terms of the composition of a structural material used during the production in the material zones 133.1-133.9, it being possible to mix structural materials with different compositions via the production method described below and thus produce any desired distribution of titanium oxide in the main body 130. The titanium oxide concentration in the main body determines the zero-crossing temperature, i.e. the temperature at which the coefficient of thermal expansion of the corresponding region of the main body is equal to zero. The method according to the disclosed techniques makes it possible to adapt the zero-crossing temperature across the main body 130 to a temperature distribution prevailing during operation of the associated projection exposure apparatus. This has the advantage that the main body 130 can be operated even in the event of temperature gradients arising across it in the case of a coefficient of thermal expansion of zero, and therefore deviations from the setpoint temperature cause no or virtually no deformations on an optical effective surface 131 formed on the main body 130. A temperature fluctuation of the main body 130 thus no longer affects the imaging quality of the projection exposure apparatus 1, 101 illustrated in FIG. 1 and FIG. 2.

FIG. 5 shows a 3D printer 40 used in the method according to the disclosed techniques for producing the optical element. It comprises an object stage 41, on which the structure of the optical element is printed. The object stage 41 is connected to a guide 46 in the z direction, with the result that the distance between the object stage 41 and a printhead 42 of the 3D printer 40 can be set. The movement range of the object stage 41 along the z axis corresponds to the maximum thickness of the optical element that can be achieved by the printing. In the embodiment depicted in FIG. 4, the printhead 42 comprises two nozzle arrays (not depicted), which print two different material mixtures. The two nozzle arrays can be actuated such that the two material mixtures can be mixed at any time in any desired mixing ratio, as a result of which the transitions of the material in the structure can be constant or abrupt. The design and the method are similar to an inkjet printer.

The number of nozzle arrays can be expanded virtually as desired, so that even further material mixtures can be used. The material mixtures 43, 44 used for the printing comprise a carrier material and a structural material and are liquid and therefore printable. The structural material is a powder which has been produced from glass or other sinterable substances and typically has a grain size of 50 μm to 150 μm. The substances used to create the powder determine the material mixture. The carrier material comprises a monomer and/or oligomer and a photoinitiator, which usually comprise onium compounds, such as aryldiazonium, diaryliodonium or triarylsulfonium, it also being possible to use other photoinitiators. As already mentioned, the material mixture of the carrier material and the structural material forms a printable liquid. The printhead 42 can be moved in the x-y plane, with the result that virtually the entire object stage 41 can be used to print the optical element. Arranged in the printhead 42, behind the nozzle arrays in the movement direction, is also a UV light 45 in the form of a curtain, which in the example shown has the same width as the nozzle arrays. The material mixtures 43, 44 are thereby polymerized by the UV light 45 directly after being applied, as a result of which the structure is built up layer by layer. The photoinitiator usually initiates a cationic polymerization by absorbing light and thereby assists and accelerates the polymerization process advantageously and is usually destroyed.

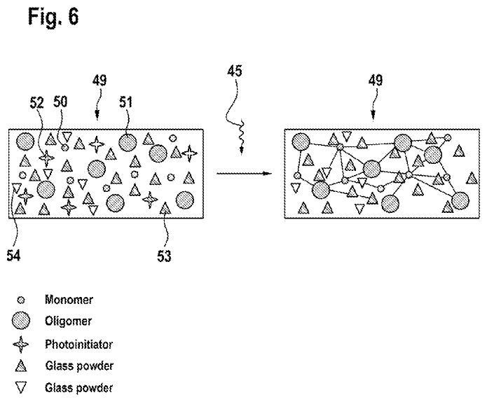

FIG. 6 shows a schematic depiction of a structure 49 printed from the material mixtures 43, 44 before and after the polymerization by the UV light 45. The material mixtures 43, 44 each comprise monomers 50, oligomers 51 and the photoinitiator 52, already illustrated in FIG. 4, as carrier material. In both material mixtures 43, 44, this carrier material contains respective different glass powders 53, 54, which differ according to the disclosed techniques in terms of their titanium concentration. The titanium concentration in the structure 49 determines, as explained above, the zero-crossing temperature, i.e. the temperature at which the coefficient of thermal expansion is zero. The printed structure 49 contains both glass powders 53, 54 made of the two material mixtures 43, 44, the glass powder 53 being distributed throughout the structure 49 and the glass powder 54 only being present on the left-hand side of the structure 49. This is intended to illustrate the possibility of any desired combination of the two material mixtures 43, 44 in the 3D printing. The right-hand side of FIG. 5 shows the structure after the polymerization of the monomers 50 and oligomers 51, which are connected to one another by lines to illustrate the crosslinking, that is brought about by the UV light 45. The photoinitiators 52 are destroyed by the UV light 45 and the glass powders 53, 54 remain in the printed position. This state is referred to as green compact, which is a dimensionally stable and solid plastics body filled with glass powder 53, 54. In the further course of the process for producing the optical element Mx, 117, the green compact is heated to above 600° Celsius. At 600° Celsius, the plastic combusts and the proportions of glass powder distributed in the plastic are sintered to one another and thus bond to one another, and therefore the structure is given its shape with minimum shrinkage. This what is referred to as brown compact is sintered in a convection furnace or microwave oven at approximately 1300° Celsius to obtain an optical element. The shrinkage, depending on the proportion of the glass powder 53, 54 in the material mixture 43, 44 as a percentage, is at 5% to 20%, in particular between 7% and 15.6%.

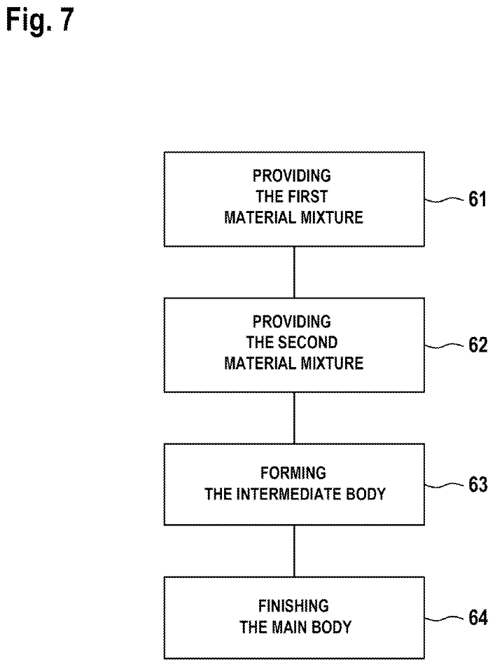

FIG. 7 describes a method for producing a main body 30 for an optical element Mx, 117.

In a first method step 61, a first material mixture comprising a first carrier material and a first structural material is provided.

In a second method step 62, a second material mixture comprising a second carrier material and a second structural material is provided.

In a third method step 63, an intermediate body is formed by merging the material mixtures and polymerizing the carrier materials.

In a fourth method step 64, at least one part of the main body is produced by heating the intermediate body to thermally bond the structural materials and to remove the carrier materials.

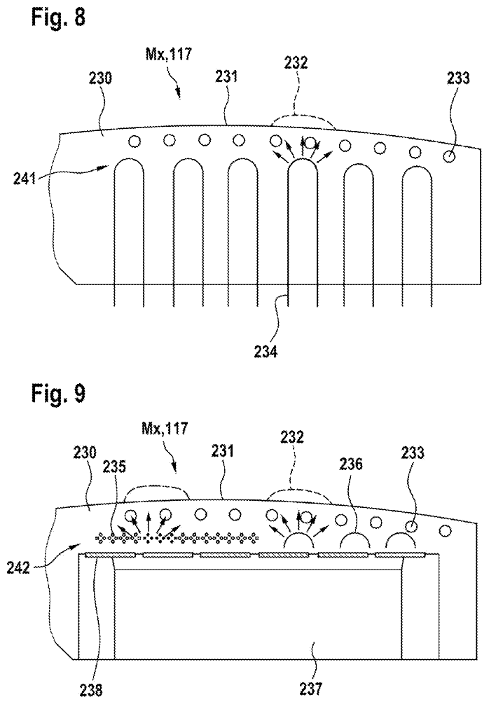

FIG. 8 shows a main body 230 for an optical element in the form of a mirror Mx, 117, as can be used in a projection exposure apparatus illustrated in FIG. 1 and FIG. 2, in a first embodiment of the disclosed techniques. The mirror Mx, 117 comprises the main body 230 with an optical effective surface 231. Formed in the main body 230, underneath the optical effective surface 231, are cooling channels 233 which control the temperature of the optical element Mx, 117 during operation, for example during operation of an associated projection exposure apparatus. Arranged in the main body 230, underneath the cooling channels 233, are actuator elements in the form of heating wires 234, which were integrated in an additive production method for the main body 230, such as 3D printing or stereolithography. Electrical current is applied via an actuator, not depicted in the figure, to the heating wires 234, which overall act as a resistance actuator 241. Owing to the ohmic resistance in the heating wire 234, a region of the main body 230 is heated, as a result of which a thermal expansion of the heated region is brought about and continues as far as the optical effective surface 231, where it leads to a deformation. By selectively actuating and regulating the temperature distribution in that region of the main body 230 that contains the heating wires 234, it is possible to use the resistance actuator 241 to set a predetermined deformation 235 on the optical effective surface 231 to correct imaging aberrations. During the temperature control, the cooling channels 233 serve as a heat sink and shield a parasitic transfer of heat from the main body 230 in the direction toward the optical effective surface 231.

FIG. 9 shows a further embodiment of a main body 230 of an optical element, which is in the form of a mirror Mx, 117 and comprises, like the optical element Mx, 117 illustrated in FIG. 8 does, cooling channels 233 arranged underneath the optical effective surface 231. By contrast to the optical element depicted in FIG. 3, electrically conductive particles 235 or electrically conductive component parts 236, such as wires or plates, are integrated in the main body 230 instead of the heating wires 234. If the main body 230 is produced with a 3D printer by the polyjet method, the particles 235 can be selectively printed, in one of the material mixtures printed with the 3D printer, at predetermined positions of the main body 230. Depending on the mixing ratio of the at least two material mixtures used in the polyjet method, it is thereby possible to deliberately set the concentration of the particles 235. This makes it possible to form individual regions with a high concentration of and regions with a low concentration of, or without, particles 235 in the main body 230.

Furthermore, it is also possible to integrate electrically conductive component parts 236 in the main body 230 during the 3D printing with the polyjet method by inserting the component parts 236. As an alternative, the component parts 236 can also be integrated in the main body 230 with other 3D printing methods which can process only one material mixture, such as stereolithography. Induction coils 238 are arranged in a recess 237 in the main body 230 and in the vicinity of the particles 235 and the component parts 236.

When an AC current is applied by an actuator, which is not depicted, they have the effect that electrical currents are induced in the particles 235 and/or component parts 236, which therefore heat up owing to their ohmic resistance. As a result, the adjacent regions in the main body 230 are also heated and a predetermined deformation of the main body 230 and thus of the optical effective surface 231 is brought about.

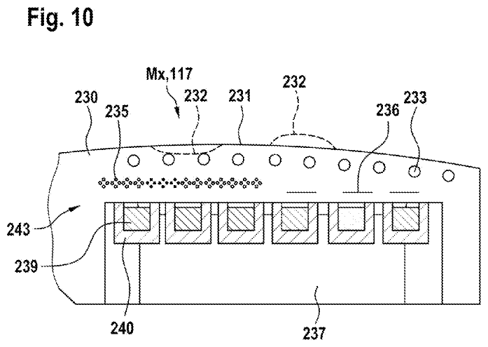

FIG. 10 shows a further embodiment of a main body 230 of an optical element in the form of a mirror Mx, 117, which comprises, like the optical element Mx, 117 illustrated in FIG. 8 and FIG. 9 does, cooling channels 233 arranged underneath the optical effective surface 231. Furthermore, the main body 230 also comprises the particles 235 and/or component parts 236 already depicted in FIG. 9. Instead of the induction coils 238, the main body 230 comprises electromagnets 239 which, like the induction coils 238 illustrated in FIG. 9, are arranged in the immediate vicinity of the particles 235 and component parts 236 in a recess 237 in the main body 230. The electromagnets 239 are received in a receptacle 240 formed on the recess 237 and, together with the magnetizable particles 235 and component parts 236, act as an electromagnetic actuator 243. The latter can, like the thermal actuators 241, 242 explained above, create a predetermined deformation in the optical effective surface 231 to correct imaging aberrations.

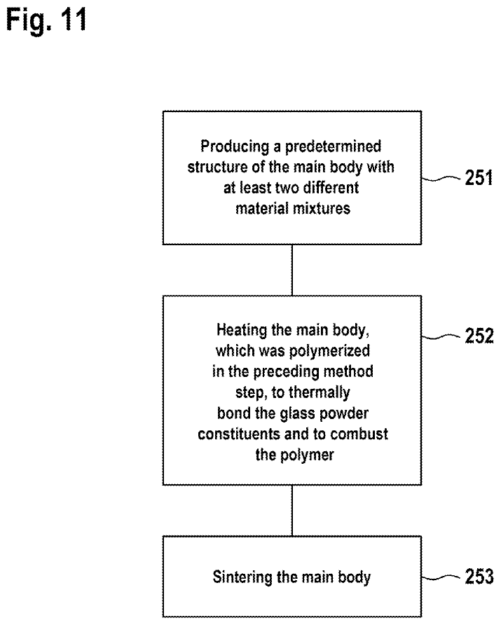

FIG. 11 describes a method for producing a main body 230 for an optical element Mx, 117.

In a first method step 251, a predetermined structure of the main body 230 is produced with at least two different material mixtures, wherein the material mixtures comprise a carrier material containing at least one monomer and/or oligomer and a structural material containing at least one glass powder, and the material mixtures differ at least by two different glass powders in the structural material.

In a second method step 252, the main body 230, that was polymerized in the preceding method step 251, is heated to thermally bond the glass powder constituents and to combust the polymer.

In a third method step 253, the main body 230 is sintered.

The actuator elements 234, 235, 236, 238, 239 and actuators 241, 242, 243 depicted in FIGS. 8 to 10 bring about, owing to the heating of certain regions of the main body 230 or owing to a magnetic force, a deformation 232 of the main body 230, which propagates as far as the optical effective surface 231. This effect is enhanced in the case of the thermal actuators 241, 242 by a high coefficient of thermal expansion in the region of the integrated actuator elements 234, 235, 236. In combination with a low coefficient of thermal expansion, i.e. a zero-crossing temperature of zero or virtually zero, in the region of the optical effective surface 231 of the main body 230, the predetermined deformation by the actuators 241, 242, 243 is maximized and the parasitic deformation by absorption of electromagnetic radiation incident on the optical effective surface is minimized. The coefficient of thermal expansion, or the zero-crossing temperature, can be varied in any desired way over the main body 230 by the production method described in FIG. 11. The main body 230 can alternatively also be used for a measurement setup or an object stage of a coordinate measuring machine and for any other application which requires a surface with high thermal stability and/or a highly accurate surface area.

### LIST OF REFERENCE SIGNS

1 Projection exposure apparatus
2 Illumination system
3 Radiation source
4 Illumination optical unit
5 Object field
6 Object plane
7 Reticle
8 Reticle holder
9 Reticle displacement drive
10 Projection optical unit
11 Image field
12 Image plane
13 Wafer
14 Wafer holder
15 Wafer displacement drive
16 EUV radiation
17 Collector
18 Intermediate focal plane
19 Deflection mirror
20 Facet mirror
21 Facets
22 Facet mirror
23 Facets
31 First method step
32 Second method step
33 Third method step
30 Main body
131 Optical effective surface
132 Connection
133 Material zones
34 Optical region
40 3D printer
41 Object stage
42 Printhead
43 Material mixture A
44 Material mixture B
45 UV light
46 X axis guide
47 Y axis guide
48 Z axis guide
49 Structure
50 Monomer
51 Oligomer
52 Photoinitiator
53 Glass powder A
54 Glass powder B
61 Method step 1
62 Method step 2
63 Method step 3
64 Method step 4
101 Projection exposure apparatus
102 Illumination system
107 Reticle
108 Reticle holder
110 Projection optical unit
113 Wafer
114 Wafer holder
116 DUV radiation
117 Optical element
118 Mounts
119 Lens housing
M1-M6 Mirrors
130 Main body
134 Optical region
230 Main body
231 Optical effective surface
232 Deformation
233 Cooling channels
234 Heating wire
235 Particle
236 Component part
237 Recess
238 Induction coil
239 Electromagnet
240 Receptacle for electromagnet
241 Resistance actuator
242 Induction actuator
243 Electromagnetic actuator
251 Method step 1
252 Method step 2
253 Method step 3

What is claimed is:

1. An additive method for producing a main body of an optical element for semiconductor lithography comprising:
providing a first material mixture comprising a first carrier material and a first structural material,
providing a second material mixture comprising a second carrier material and a second structural material,
wherein the first carrier material and the second carrier material comprise at least one monomer and/or at least one oligomer and wherein the first structural material and the second structural material differ in terms of their composition,
forming an intermediate body by merging the first material mixture and the second material mixture and polymerizing the first carrier material and the second carrier material,
finishing at least one part of the main body by heating the intermediate body to thermally bond the first structural material and the second structural material and to remove the first carrier material and the second carrier material.

2. The method of claim 1, wherein the forming the intermediate body is performed using a polyjet printing method.

3. The method of claim 2, wherein at least one of the first structural material or the second structural material contains a glass powder.

4. The method of claim 3, wherein at least one of the first structural material or the second structural material contains an additive.

5. The method of claim 4, wherein the first structural material and the second structural material differ in terms of a type of additive.

6. The method of claim 4, wherein the first structural material and the second structural material differ in terms of a concentration of additives.

7. The method of claim 4, wherein the additive comprises one or more of the following substances or compounds: titanium, titanium oxide, lithium, aluminum, OH compounds.

8. The method of claim 4, wherein a concentration of additives over the main body corresponds to a temperature distribution, established during use of the optical element, in the main body.

9. The method of claim 8, wherein the concentration of additives decreases as the distance from a side of the main body that is intended for an optical surface increases.

10. The method of claim 9, wherein the concentration of additives constantly decreases as the distance from a side of the main body that is intended for an optical surface to a cooled layer in the main body increases.

11. The method of claim 1, wherein the method is used to produce an optical element for a projection exposure apparatus for semiconductor lithography.

12. A main body for an optical element, the main body being produced at least partially by an additive method, the zero-crossing temperature of the coefficient of linear thermal expansion changing at least in a partial region of the main body, wherein the change in the zero-crossing temperature is continuous in the partial region of the main body.

13. The main body of claim 12, wherein the change in the zero-crossing temperature ranges from 20° Celsius to 65∪ Celsius at more than 1 K/mm.

14. The main body of claim 12, wherein the zero-crossing temperature which varies at least partially over the main body corresponds to a temperature distribution, established during use of the optical element, in the main body.

15. A main body for an optical element, the main body comprising:
at least one actuator and/or sensor, wherein at least one actuator component of the actuator and/or one sensor component of the sensor is integrated at least in an additively manufactured partial structure of the main body.

16. The main body of claim 15, wherein the actuator component and/or the sensor component is an electrically conductive element.

17. The main body of claim 16, wherein the actuator component and/or the sensor component comprises at least one heating wire, electrically conductive particles and/or electrically conductive component parts.

18. The main body of claim 15, wherein the actuator component and/or the sensor component comprises a magnetizable element or a thermally conductive element.

19. A projection exposure apparatus for semiconductor lithography, comprising an optical element having a main body as claimed in claim 12.

20. The projection exposure apparatus for semiconductor lithography of claim 19ss, wherein:
the main body of the optical element is built up layer by layer and within the main body there are material property inhomogeneities, the optical element being arranged in the projection exposure apparatus in such a way that the direction of the greatest inhomogeneities runs substantially perpendicularly in relation to a scanning direction of the projection exposure apparatus.
